(19) United States
(12) Patent Application Publication
(10) Pub. No.: US 2025/0022982 A1
(43) Pub. Date: Jan. 16, 2025

(54) DEVICE FOR FACILITATING EMITTING LIGHT AND A METHOD FOR MANUFACTURING THE DEVICE

(71) Applicants: Yungryel Ryu, IRVINE, CA (US); Mun Whan Bang, Pyeongtaek-si (KR)

(72) Inventors: Yungryel Ryu, IRVINE, CA (US); Mun Whan Bang, Pyeongtaek-si (KR)

(21) Appl. No.: 18/770,631

(22) Filed: Jul. 11, 2024

Related U.S. Application Data
(60) Provisional application No. 63/512,977, filed on Jul. 11, 2023.

(51) Int. Cl. H01L 33/12; H01L 33/00; H01L 33/24; H01L 33/28; H01L 33/32; H01L 33/40; H01L 33/42; H01L 33/44; H01S 5/22; H01S 5/343

(52) U.S. Cl. CPC H01L 33/12; H01L 33/0095; H01L 33/24; H01L 33/28; H01L 33/32; H01L 33/405; H01L 33/42; H01L 33/44; H01S 5/22; H01S 5/34333; H01S 5/34346; H01L 2933/0016; H01L 2933/0025

(57) ABSTRACT

A device for facilitating emitting light is disclosed. Accordingly, the device may include at least one substrate, at least one first layer configured to be placed on the at least one substrate. Further, the at least one first layer may be an n-type nitride based semiconductor layer. At least one second layer configured to be placed on the at least one first layer. Further, the at least one second layer may be a nitride based semiconductor. At least one third layer configured to be placed on the at least one second layer. Further, the at least one third layer may be a p-type semiconductor layer. At least one fourth layer configured to be placed on the at least one third layer. Further, the at least one fourth layer may include at least one transparent electrode.

### FIELD OF THE INVENTION

Generally, the present disclosure relates to the field of semiconductor device manufacturing. More specifically, the present disclosure relates to a device for facilitating emitting light and a method for manufacturing the device.

### BACKGROUND OF THE INVENTION

The field of semiconductor device manufacturing is technologically important to several industries, business organizations, and/or individuals. In particular, the use of semiconductor device manufacturing is prevalent for a device for facilitating emitting light and a method for manufacturing the device.

The luminous efficiency of the GaN-based light emitting devices has been improved since Dr. Shuji Nakamura demonstrated his first blue LED. These GaN-based light emitting devices are composed of nitride semiconductors with different lattice distances such as GaN, InGaN, AlGaN and AlInGaN. Tensile or compressed strain is commonly observed in the structure configured with nitride layers having different lattice distances. Such strain can lower the internal quantum efficiency (IQE) for light emitting devices. For example, GaN-based light emitting devices such as LED and LD emit light from the active layer composed of the GaN barrier and InGaN well or the AlGaN barrier and GaN well. The lattice mismatch among GaN, InGaN, and AlGaN thin film layers can create strain in the active layer, where an internal electric field such as a piezoelectric field would be built up due to such strain. The piezoelectric field formed in the active layer makes the IQE lowered resulting in low luminous efficiency.

In addition to the problem of lattice constant mismatching, another problem to be solved for GaN-based light emitting devices is that the density and mobility of hole carriers injected from the p-type layer are much lower than the density and mobility of electron carriers injected from the n-type layer. As a result, the number of holes injected into the active layer is much smaller than that of electrons. Therefore, the probability for light emission, created from recombination of electrons and holes, becomes lowered as the injected current increases. It causes the internal quantum efficiency (IQE) to be decreased (called an efficiency droop phenomenon) as the injected current increases. Therefore, if more holes can be supplied from the p-type layer to the active layer, the IQE for the GaN-based light emitting devices may be significantly improved and the phenomenon of decreasing the IQE may be disappeared.

In order to increase the IQE by preventing electrons overflowing from the active layer to the p-type layer without emitting light due to insufficient holes, Dr. Nakamura applied a structure of AlGaN layer to block electron overflowing (EBL) for GaN-based light emitting devices. However, for introduction of the EBL layer, many electrons may be accumulated at the boundary between the EBL layer and the adjacent QW, causing another problem. In other words, both electrons accumulated at the boundary of the EBL layer and ionized atoms of activated donor impurities in the n-type layer create a strong electric field in the active layer region, which generates strain in the QWs. Such strain causes a negative effect of reducing the IQE.

As the strain caused by the lattice mismatch and the hole-electron imbalance creates an electric field in the active layer, which not only interferes with the flow of holes and electrons injected from the p-type and n-type layers but also lowers the probability of recombining holes and electrons for light emission. Therefore, if the strain generated by the crystal lattice mismatch and insufficient holes is removed, the IQE must have been dramatically improved.

Existing techniques for semiconductor device manufacturing are deficient with regard to several aspects. For instance, current technologies do not provide a solution for undercuts during etching. As a result different technology is required for providing a solution for undercuts during etching. Furthermore, current technologies do not provide a method for fabricating high quality zinc-oxide based semiconductor. As a result, different technology is required to provide a method for fabricating high quality zinc-oxide based semiconductor. Moreover, current technologies do not provide a method for precise etching of zinc-oxide based semiconductor. As a result, different technology is needed to provide a method for precise etching of zinc-oxide based semiconductors.

Therefore, there is a need for improved technology for facilitating a device for facilitating emitting light and a method for manufacturing the device that may overcome one or more of the above-mentioned problems and/or limitations.

### SUMMARY OF THE INVENTION

This summary is provided to introduce a selection of concepts in a simplified form, that are further described below in the Detailed Description. This summary is not intended to identify key features or essential features of the claimed subject matter. Nor is this summary intended to be used to limit the claimed subject matter's scope.

Disclosed herein is a device for facilitating emitting light, in accordance with some embodiments. Accordingly, the device may include at least one substrate. Further, the device may include at least one first layer configured to be placed on the at least one substrate. Further, the at least one first layer may be an n-type nitride based semiconductor layer. Further, the at least one first layer may be a base of a mesa structure. Further, the base of the mesa structure may be etched using an etching process. Further, the device may include at least one second layer configured to be placed on the at least one first layer. Further, the at least one second layer may be a nitride based semiconductor. Further, the at least one second layer may be a second layer of the mesa structure. Further, the second layer of the mesa structure may be etched using the etching process. Further, the device may include at least one third layer configured to be placed on the at least one second layer. Further, the at least one third layer may be a p-type semiconductor layer. Further, the at least one third layer may be a third layer of the mesa structure. Further, the third layer of the mesa structure may be etched using a first etching process. Further, the device may include at least one fourth layer configured to be placed on the at least one third layer. Further, the at least one fourth layer may include at least one transparent electrode. Further, the at least one fourth layer may be a fourth layer of the mesa structure. Further, the fourth layer of the mesa structure may be etched using the etching process.

Further disclosed herein is a method for manufacturing a light emitting device, in accordance with some embodiments. Accordingly, the method may include a step of sequentially stacking at least one first layer, at least one second layer, at least one third layer, and at least one fourth layer, on a substrate. Further, the at least one first layer may be an n-type nitride based semiconductor layer. Further, the at least one second layer may be a nitride based semiconductor layer. Further, the at least one third layer may be a p-type semiconductor layer. Further, the at least one fourth layer may include at least one transparent electrode. Further, the method may include a step of forming a photoresist pattern associated with a mesa structure on the at least one fourth layer. Further, the photoresist pattern may be associated with a size. Further, the method may include a step of etching the at least one fourth layer based on the photoresist pattern using a dry etching process. Further, the dry etching process may include using ionized gases for etching. Further, the method may include a step of etching the at least one third layer based on the photoresist pattern using a wet etching process. Further, the wet etching process may include using at least one of chemical solutions, chemical vapors, etc. Further, the method may include a step of forming a first photoresist pattern associated with the mesa structure on the at least one second layer. Further, the first photoresist pattern may be associated with a first size. Further, the method may include a step of etching the at least one second layer based on the first photoresist pattern using the etching process. Further, the method may include a step of removing the photoresist pattern, the first photoresist pattern, and by-product residues.

Both the foregoing summary and the following detailed description provide examples and are explanatory only. Accordingly, the foregoing summary and the following detailed description should not be considered to be restrictive. Further, features or variations may be provided in addition to those set forth herein. For example, embodiments may be directed to various feature combinations and sub-combinations described in the detailed description.

### BRIEF DESCRIPTION OF THE DRAWINGS

The accompanying drawings, which are incorporated in and constitute a part of this disclosure, illustrate various embodiments of the present disclosure. The drawings contain representations of various trademarks and copyrights owned by the Applicants. In addition, the drawings may contain other marks owned by third parties and are being used for illustrative purposes only. All rights to various trademarks and copyrights represented herein, except those belonging to their respective owners, are vested in and the property of the applicants. The applicants retain and reserve all rights in their trademarks and copyrights included herein, and grant permission to reproduce the material only in connection with reproduction of the granted patent and for no other purpose.

Furthermore, the drawings may contain text or captions that may explain certain embodiments of the present disclosure. This text is included for illustrative, non-limiting, explanatory purposes of certain embodiments detailed in the present disclosure.

FIG. 1 is a partial sectional view of a device 100 for facilitating emitting light, in accordance with some embodiments.

FIG. 2 is a partial sectional view of the device 100 for facilitating emitting light, in accordance with some embodiments.

FIG. 3 is a partial sectional view of the device 100 for facilitating emitting light, in accordance with some embodiments.

FIG. 4 is a partial sectional view of the device 100 for facilitating emitting light, in accordance with some embodiments.

FIG. 5 is a partial sectional view of the device 100 for facilitating emitting light, in accordance with some embodiments.

FIG. 6 is a flow diagram of a method 700 for facilitating manufacturing a light emitting device, in accordance with some embodiments.

FIG. 7 is a flowchart of a method 800 for facilitating manufacturing a light emitting device, in accordance with some embodiments.

FIG. 8 is a flow diagram of a method 900 for facilitating manufacturing a light emitting device, in accordance with some embodiments.

FIG. 9 is a flow diagram of a method 1000 for facilitating manufacturing a light emitting device, in accordance with some embodiments.

FIG. 10 is a flow diagram of a method 1100 for facilitating manufacturing a light emitting device, in accordance with some embodiments.

FIG. 11 shows a surface image of a structure of a transparent electrode material (ITO) and ZnO etched with diluted HCl solution, in accordance with some embodiments.

FIG. 12 shows a surface image of a structure of a transparent electrode material (ITO) and ZnO etched with diluted HCl solution, in accordance with some embodiments.

FIG. 13 shows an epi structure 1400 of a ZOGaN light emitting device composed of a ZnO-based oxide semiconductor layer and a GaN-based nitride semiconductor layer, in accordance with some embodiments.

FIG. 14 shows a flip-chip type ZOGaN light emitting device 1500, in accordance with some embodiments.

FIG. 15 shows a lateral type ZOGaN light emitting device 1600, in accordance with some embodiments.

FIG. 16 shows a fine pattern 1700 fabricated using an etching process, in accordance with some embodiments.

FIG. 17 shows a lateral view of a fine pattern 1800 fabricated using an etching process, in accordance with some embodiments.

### DETAILED DESCRIPTION OF THE INVENTION

As a preliminary matter, it will readily be understood by one having ordinary skill in the relevant art that the present disclosure has broad utility and application. As should be understood, any embodiment may incorporate only one or a plurality of the above-disclosed aspects of the disclosure and may further incorporate only one or a plurality of the above-disclosed features. Furthermore, any embodiment discussed and identified as being “preferred” is considered to be part of a best mode contemplated for carrying out the embodiments of the present disclosure. Other embodiments also may be discussed for additional illustrative purposes in providing a full and enabling disclosure. Moreover, many embodiments, such as adaptations, variations, modifications, and equivalent arrangements, will be implicitly disclosed by the embodiments described herein and fall within the scope of the present disclosure.

Accordingly, while embodiments are described herein in detail in relation to one or more embodiments, it is to be understood that this disclosure is illustrative and exemplary of the present disclosure, and are made merely for the purposes of providing a full and enabling disclosure. The detailed disclosure herein of one or more embodiments is not intended, nor is to be construed, to limit the scope of patent protection afforded in any claim of a patent issuing here from, which scope is to be defined by the claims and the equivalents thereof. It is not intended that the scope of patent protection be defined by reading into any claim limitation found herein and/or issuing here from that does not explicitly appear in the claim itself.

Thus, for example, any sequence(s) and/or temporal order of steps of various processes or methods that are described herein are illustrative and not restrictive. Accordingly, it should be understood that, although steps of various processes or methods may be shown and described as being in a sequence or temporal order, the steps of any such processes or methods are not limited to being carried out in any particular sequence or order, absent an indication otherwise. Indeed, the steps in such processes or methods generally may be carried out in various different sequences and orders while still falling within the scope of the present disclosure. Accordingly, it is intended that the scope of patent protection is to be defined by the issued claim(s) rather than the description set forth herein.

Additionally, it is important to note that each term used herein refers to that which an ordinary artisan would understand such term to mean based on the contextual use of such term herein. To the extent that the meaning of a term used herein—as understood by the ordinary artisan based on the contextual use of such term—differs in any way from any particular dictionary definition of such term, it is intended that the meaning of the term as understood by the ordinary artisan should prevail.

Furthermore, it is important to note that, as used herein, “a” and “an” each generally denotes “at least one,” but does not exclude a plurality unless the contextual use dictates otherwise. When used herein to join a list of items, “or” denotes “at least one of the items,” but does not exclude a plurality of items of the list. Finally, when used herein to join a list of items, “and” denotes “all of the items of the list.”

The following detailed description refers to the accompanying drawings. Wherever possible, the same reference numbers are used in the drawings and the following description to refer to the same or similar elements. While many embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the claims found herein and/or issuing here from. The present disclosure contains headers. It should be understood that these headers are used as references and are not to be construed as limiting upon the subjected matter disclosed under the header.

The present disclosure includes many aspects and features. Moreover, while many aspects and features relate to, and are described in the context of a device for facilitating emitting light and a method for manufacturing the device, embodiments of the present disclosure are not limited to use only in this context.

### Overview

The present disclosure describe a device for facilitating emitting light and a method for manufacturing the device.

Further, the present disclosure describes a method for solving the problems of GaN-based light emitting devices and improving the device performance, YungRyel Ryu of the present invention has developed the ZOGaN light emitting device (ZOGaN LED/LD) composed of nitride semiconductor and oxide semiconductor. Nitride semiconductors may be GaN, InN, AlN, InGaN, AlGaN, or AlInGaN, and oxide semiconductors may be any oxide semiconductor containing Zn-atom. These materials are called GaN-based nitride semiconductors and ZnO-based oxide semiconductors, respectively.

The present disclosure relates to a chip process developed to fabricate a light emitting device, called ZOGaN light emitting device, composed of ZnO-based oxide semiconductor and GaN-based nitride semiconductor. The process method of the present invention makes it possible to etch a GaN-based nitride semiconductor and a ZnO-based oxide semiconductor can be separately etched one by one without being etched together at the same time. In more detail, the present invention relates to an etching process method to selectively etch different materials composing ZOGaN light emitting devices and a method for manufacturing the ZOGaN light emitting device using the same.

Further, for ZOGaN LED/LD with a p-type layer composed of either a ZnO-based p-type oxide semiconductor or a ZnO-based p-type oxide semiconductor combined with a GaN-based p-type nitride semiconductor, the p-type layer has poor electrical conductivity. Therefore, a p-electrode layer with excellent electrical conductivity and optical transparency in visible light wavelengths deposited on the surface of the ZnO-based oxide layer is required, in order to supply hole carriers into the active layer uniformly from the whole area of the p-type layer when the ZOGaN LED/LD operates. Meanwhile, unlike GaN-based nitride semiconductors, ZnO-based oxide semiconductor actively reacts with all types of acid and base chemicals. Due to such chemical characteristics of ZnO-based oxide semiconductors, ZOGaN LED/LD light emitting devices cannot be manufactured with conventional photolithographic and etching processes, if the ZnO-based oxide semiconductor is not protected from chemicals used in the chip fabrication process. Therefore, the transparent p-electrode layer should be deposited on the entire surface of the ZnO-based oxide semiconductor not only to uniformly inject hole particles through the entire ZnO-based p-type oxide layer into the active layer but also to protect the ZnO-based oxide semiconductor layer from chemicals used in chip fabrication process. From the device structure point of view, the transparent p-electrode layer should be one of the required layers for ZOGaN LED/LD, to protect the ZnO-based oxide semiconductor layer.

Further, the p-n junction mesa of the GaN-based light-emitting devices may be accomplished by a conventionally known etching process. For manufacturing the GaN-based light emitting devices composed of a GaN-based nitride semiconductor layer structure and a transparent electrode layer, etching GaN-based nitride semiconductor layers may be usually performed by an ICP or RIE dry etching method with (BCl3, Cl2, Ar)-based gases, while the transparent electrode layer may be etched by an acid solution-based wet etching method so that a p-n junction mesa pattern is formed.

Further, the present disclosure describes a conventional acid solution-based wet etching process used for etching the transparent electrode layer formed on the GaN-based nitride semiconductor, the ZnO-based p-type oxide semiconductor and the transparent electrode cannot be sharply etched out without leaving a residue along the etched line. Therefore, a conventional wet etching process is not suitable for manufacturing the ZOGaN LED/LD.

Further, the present disclosure describes the problems in wet etching created by the difference in chemical properties of the ZnO-based oxide semiconductor and the material constituting the transparent electrode layer. That is, since the etching rate of the ZnO-based oxide semiconductor is more than five times faster than the etching rate of the transparent electrode layer, etching the ZnO-based semiconductor may be started before the transparent electrode layer is fully removed by etching. Therefore, a severe undercut of the ZnO-based oxide semiconductor layer located below the transparent electrode layer may have happened. In addition, the compounds (maybe formed with elements constituting ZnO-based oxide semiconductor, the transparent electrode, and the chemical solution of etchant) produced in a wet etching process are hard to remove by the etching solution used in the wet etching process. For these reasons, the conventional wet etching method is not useful for etching at the same time the ZnO-based oxide semiconductor layer and the transparent electrode layer for manufacturing the ZOGaN LED/LD.

Further, the present disclosure describes a conventional dry etching process with the (BCl3, Cl2, Ar)-based mixed gas, commonly used to etch out GaN-based nitride semiconductor, is not good for fabricating the ZOGaN LED/LD because the (BCl₃, Cl₂, Ar)-based dry etching process is not effective to remove ZnO-based oxide semiconductor. The etching rate of ZnO-based oxide semiconductors is more than 10 times slower than the etching rate of GaN-based nitride semiconductors, and also the etching uniformity of ZnO-based oxide semiconductors is not good. For these reasons, all known dry etching processes are not useful for manufacturing the ZOGaN LED/LD.

Further, the present disclosure describes the technical difficulties or problems described above, extremely expensive and special facilities are required for fine pattern alignment of less than 1 micrometer to fabricate ultra-high resolution full-color pixels for the VR (virtual reality) or AR (augmented reality) displays. It is conventional that an insulating film on the etched surface of the ZOGAN LED/LD is deposited with a new photoresist pattern, following the process of removing/cleaning a photoresist pattern used for the etching process. The production yield may be lowered because fine pattern alignment from an ultra-high resolution pattern is difficult although special equipment is used. Therefore, the smaller the process steps are for ultra-high resolution products, the higher yield and more efficient production may be accomplished.

Further, in the present disclosure, a new process method was developed for ZOGAN LED/LD fabrication. The multilayer structure composed of GaN-based nitride semiconductor, ZnO-based oxide semiconductor, and a transparent electrode material can be effectively etched layer by layer to form the ZOGAN LED/LD, as described in this invention. Further, the etched surface can be easily treated and deposited with an insulating layer for surface passivation, sequentially following the etching process without a new photolithography process, unlike conventional processes.

Further, the desirable results of the present invention are described in the embodiments below. Some examples relevant to explain the present invention are included in the publications below. Further, the ZnO oxide semiconductor is like GaN in optical and electrical properties. In addition to these properties, the US patent (U.S. Pat. No. 6,291,085, inventor: White et al.) discloses doped p-type ZnO thin film applicable for the semiconductor devices including, but not limited to, LEDs and LDs.

Further, the U.S. patent (U.S. Pat. No. 6,342,313, inventor: White, et al.) discloses a p-type metal oxide thin film with a doping concentration of at least 10¹⁵ acceptors/cm³ or more, wherein the thin film includes oxide compounds based on Group 2 elements (Be, Mg, Ca, Sr, Ba, and Ra), oxide compounds based on Group 12 elements (Zn, Cd, and Hg), oxide compounds based on both elements of groups 2 and 12, and ones based on elements of groups 12 and 16 (O, S, Se, Te and Po), and the acceptor impurities for doping may be single or plural elements chosen among Group 1 (H, Li, Na, K, Rb, Cs, Fr), Group 11 (Cu, Ag, Au), Group 5 (V, Nb, Ta), and Group 15 (N, P, As, Sb, Bi) in periodic table.

Further, the following papers report that the defect of Zn-vacancy in ZnO is an acceptor, which may be created in either growing ZnO-based oxide semiconductor in an oxygen-rich condition or in annealing at a high temperature in an oxygen-contained environment after growth. The hole concentration in ZnO-based oxide semiconductors may be increased by increasing the concentration of Zn-vacancy.

Further, the present disclosure describes a chip process method of the present invention that has been developed for manufacturing a new light-emitting device (called ZOGaN LED/LD). This invented method can make manufacturing of ZOGaN LED/LD, resulting in a high production yield. The etching process of the present invention can efficiently etch the structure composed of a transparent layer, ZnO-based oxide, and GaN-based nitride semiconductors of ZOGaN LED/LD. Thereby, the invented etching process can facilitate ZOGaN LED/LD production.

The present disclosure is to develop a novel etching process suitable for fabricating the mesa of the ZOGaN LED/LD composed of TCO material, ZnO-based oxide semiconductor, and GaN-based nitride semiconductor. Furthermore, it is to provide a process method for manufacturing the ZOGaN LED/LD by using the etching process of the present invention.

Further, the present disclosure describes The ZOGaN LED/LD is made of the epi structure composed of ZnO-based oxide semiconductor and GaN-based nitride semiconductor layers, which was developed to solve the weakness and problems of conventional GaN-based light emitting devices.

Further, the present disclosure describes that The ZOGaN LED/LD is composed of the n-type layer supplying electrons, the active layer emitting light, and the p-type layer supplying holes.

Further, the present disclosure describes that the n-type layer is composed of variable GaN-based n-type nitrides such as n-type GaN, n-type InGaN, and n-type AlGaN.

Further, the active layer is composed of the GaN-based barrier and well layers, wherein the barrier layer has a larger energy bandgap than the well layer. The active layer may be comprised of InGaN layers with different In-atom composition ratios, such as GaN and InGaN layers, and AlGaN and GaN layers.

Further, the p-type layer is formed by GaN-based nitride semiconductor and ZnO-based oxide semiconductor layers. The ZnO-based oxide semiconductor layer is deposited on the top layer of the GaN-based nitride semiconductor layers.

Further, the transparent p-electrode layer of TCO material is deposited on the top surface of the ZO-based oxide semiconductor layer, which provides good current spreading as well as protects the ZnO-based p-type oxide semiconductor layer.

Further, the present disclosure describes the epi structure of ZOGaN LED/LD may be accomplished by depositing the ZnO-based oxide semiconductor layer on the substrate composed of the GaN-based nitride semiconductor layers, which is already patterned with the p-n junction mesa for light emitting devices.

Further, the present disclosure describes that the GaN-based p-type nitride semiconductor layer may be composed of one or more layers comprising InGaN, GaN, or AlGaN.

Further, in an embodiment of the present invention, the p-type layer of the ZOGaN LED/LD may be composed of the ZnO-based p-type oxide semiconductor layer in 1˜1,000 nm thick deposited on the GaN-based p-type nitride semiconductor layer. The ZnO-based oxide semiconductor is in hexagonal crystal structure as InGaN, GaN, and AlGaN. The ZnO-based oxide semiconductor is an oxide composed of Group II elements and Group VI elements in the periodic table, including ZnO, BeZnO, MgZnO, BeMgZnO, ZnSO, ZnSeO, ZnSSeO, ZnCdO, and ZnCdSeO. The ZnO-based oxide semiconductor layer may be doped at an acceptor impurity level of 1×10¹⁷ cm⁻³ or higher. The ZnO-based oxide semiconductor layer may be deposited in an oxygen-rich condition on the surface of the p-type nitride semiconductor layer so that the ZnO-based oxide semiconductor layer has a Zn-vacancy concentration at the level of 1×10¹⁷ cm⁻³ or higher to supply enough holes to the active layer. The ZOGaN LED/LD may be fabricated by using a conventional photolithographic process and the chip fabrication process of the present invention.

Further, the present disclosure describes that the ZOGaN LED/LD with a TCO electrode may be fabricated in two processes dry etching and one wet etching process. That is, after a required pattern for the process is formed with photoresist in a photolithographic process, the mesa pattern may be accomplished in three steps for different etching purposes, wherein 1) the 1^{st} step of dry etching: a TCO electrode layer is etched out in a dry etching process based on the gases selected from BCl₃, Cl₂, Ar (but not limited to). The znO-based oxide semiconductor material is slowly etched in the dry etching process with these gases; 2) the 2^{nd} step of wet etching: the ZnO-based oxide semiconductor layer is easily etched out in a wet etching process with diluted chemical solution or vapor (gas phase), selected from at least one of following chemicals (but not limited to); Ferric Chloride, all kinds of acid and base chemicals in solutions or vapor (gas phase), which do not etch GaN-based nitride semiconductor at all. After the wet etching process is done, photoresist and by-product residues are removed for cleaning the surface; 3) the 3^{rd} step of dry etching: after making a new pattern with photoresist a little bigger than the size of the pattern formed in the 1^{st} and 2^{nd} steps, GaN-based nitride semiconductor layer is etched out to form a mesa pattern of p-n junction in a dry etching process with the gases selected from BCl₃, Cl₂, Ar (but not limited to). Finally, the process of making the mesa pattern may be finished by cleaning to remove photoresist and by-product residues created in the etching process. Similarly, as described above, the 3^{rd} etching process may be first applied to form the mesa pattern of a p-n junction with the LED epi wafer composed of GaN-based nitride semiconductor, before ZnO film is deposited. After depositing the ZnO-based oxide semiconductor layer and the transparent electrode layer on the mesa-patterned wafer, the final mesa of the p-n junction for the ZOGaN LED/LD can be finished in the 1^{st} and 2^{nd} processes described above.

Further, the present disclosure describes that the 3^{rd} step to etch the GaN-based nitride semiconductor layer is continued to finish the remaining steps without changing the photoresist pattern after finishing the ZnO-based oxide semiconductor layer in the 2^{nd} step process, as done before. The other embodiment of the present invention describes adding additional steps of cleaning the etched surface and depositing an insulating layer for surface passivation before removing the photoresist pattern just after finishing all steps. As the process in previous embodiments, two different works of etching and surface passivation can be accomplished under one process, resulting in skipping an alignment step of forming a photoresist pattern required for depositing an insulating layer.

Further, the present disclosure describes, in an embodiment, a thermal annealing process should be performed in a gas containing oxygen (with or without oxygen plasma treatment done before the thermal annealing process) in order to clean the impurities and cure the damaged surface possibly caused in the etching process. The thermal annealing process is performed after cleaning the photoresist and by-product residues. Thermal annealing in a gas containing oxygen may remove a potential barrier possibly formed at the interfaces among GaN, ZnO, and ITO as well as increase the hole concentration in the p-layer through Zn-atom diffusion into the p-GaN layer and Mg-atom diffusion out to the ZnO layer. The TCO layer may act like a barrier not to evaporate Zn-atom out to the air but to diffuse into the neighbor layer of p-type GaN-based nitride semiconductor during the thermal annealing process. Both diffusion of Zn-atom from the p-type ZnO-based oxide layer in the p-type nitride layer and diffusion of Mg-atom from the p-type nitride layer out to the p-type ZnO layer may increase the hole concentration in the p-type layer. For specific applications, an additional process such as surface passivation with insulating material may be necessary to protect the ZOGaN LED/LD.

Further, the present disclosure describes that for the fabrication of ZOGaN LEDs/LDs, GaN-based nitride semiconductor and ZnO-based oxide semiconductor layers can be selectively and precisely etched by the above-described etching process. The etching process of the present invention is useful to fabricate small-sized ZOGaN LEDs/LDs such as the micro or nano LEDs/LDs required for the next-generation display. Furthermore, fabricating the mesa structure of the ZOGaN LED/LD may be simplified by using the etching process of the present invention. Therefore, the ZOGaN LED/LD can be manufactured with a high production yield rate, resulting in lowering the manufacturing cost for the ZOGaN LED/LD.

Further, the present disclosure describes that embodiments of the present invention may be changed in various forms, and the scope of the present invention is not limited to the embodiments described below.

Further, the present disclosure describes that the structure of the ZOGaN LED/LD is composed of ZnO-based oxide semiconductors and GaN-based nitride semiconductors. The n-type layer is composed of at least one layer of n-type GaN, n-type InGaN, and n-type AlGaN, to supply electrons to the active layer. Further, the active layer structure comprises a quantum well (QW) made of a GaN-based nitride semiconductor with an energy bandgap and a quantum barrier (QB) made of a GaN-based nitride semiconductor with an energy bandgap larger than the energy bandgap of the QW. Light emits from the active layer through the recombination of electrons and holes. Further, the p-type layer deposited on the active layer (20), serves to supply holes to the active layer. Further, the p-type layer of the ZOGaN LED/LD in an embodiment of the present invention is the hybrid epi structure composed of the GaN-based p-type nitride semiconductor layer and the ZnO-based oxide semiconductor layer. Further, the GaN-based p-type nitride semiconductor layer is composed of one or more layers selected from p-type InGaN, p-type GaN, or p-type AlGaN layers.

Further, in an embodiment of the present invention, the ZnO-based p-type oxide semiconductor layer is deposited on the p-type nitride semiconductor layer by the HBD epitaxy single crystal growth method, but not limited to.

Further, an embodiment of the present disclosure describes the ZnO-based oxide semiconductor layer may be doped to supply enough holes to the active layer (20) with at least one acceptor impurity, selected from the acceptor impurity group including H, Li, Na, K, Rb, Cs, Fr, H, Li, Na, K, Rb, Cs, Fr, Cu, Ag, N, P, As, Sb, and Bi, preferably N, P, and As, and more preferably As.

Further, in another embodiment of the present invention described above the ZnO-based oxide semiconductor layer may be composed of Zn-deficient ZnO-based oxide semiconductor to supply enough holes to the active layer.

Further, in an embodiment of the present invention, the ZnO-based oxide semiconductor of the layer is in a hexagonal crystal structure with a lattice distance larger than the lattice distance of the GaN semiconductor. The ZnO-based oxide semiconductor may be composed of one or more selected from ZnO, BeZnO, MgZnO, BeMgZnO, ZnSO, ZnSeO, ZnSSeO, ZnCdO, ZnCdSeO (but not limited to).

Further, in an embodiment of the present invention, the p-electrode is composed of a TCO electrode layer deposited on the ZnO-based oxide semiconductor layer. The TCO electrode layer may be made of a TCO material such as ITO, NiO, GaZnO, InZnO, InGaZnO, and so forth. The TCO electrode layer and the ZnO-based oxide semiconductor layer may be first etched out for fabricating the ZOGaN LED/LD. The etching process of the present invention may be performed after the area not to be etched is covered with a photoresist pattern. The photoresist pattern may be formed in a conventional photolithography process. Further, for forming the mesa of the ZOGaN LED/LD with a TCO electrode layer, the TCO electrode layer may be first etched out at an etching rate of 10 to 100 nm per minute in a dry etching process with a (BCl₃, Cl₂, Ar)-based mixed gas (but not limited to). In this case, since the ZnO-based oxide semiconductor is a hard material to be etched with these gases, the ZnO-based oxide semiconductor layer can well protect the GaN-based nitride semiconductor layer until the TCO layer is fully etched out in the dry etching process. After the dry etching process of removing the TCO electrode layer is completed, the ZnO-based oxide semiconductor layer may be etched at an etching rate of 0.1 to 10 μm per minute in a wet etching process by an etchant made of Ferric Chloride, various acids, or base chemicals. In this case, the etching rate of the ZnO-based oxide semiconductor is more than five times faster than the etching rate of the TCO electrode layer. Therefore, the lateral etching (undercut) of the TCO electrode layer during the etching of the ZnO-based oxide semiconductor layer is almost negligible.

Further, in an embodiment, after completing the etching process of the ZnO-based oxide semiconductor layer and the TCO electrode layer, the partially processed wafer may be cleaned to remove the photoresist and residues to form a new photoresist pattern of the mesa before etching GaN-based nitride semiconductor. In this case, the photoresist pattern is larger than the pattern composed of the etched ZnO-based oxide semiconductor layer and the etched TCO electrode layer.

Further, in an embodiment, forming a photoresist pattern to etch the GaN-based nitride semiconductor layer is not always necessary. The process of etching GaN-based nitride semiconductors may be continued without changing the photoresist pattern used in the etching process to remove the ZnO-based oxide semiconductor layer and the TCO layer. Further, the mesa of the p-n junction for the ZOGaN LED/LD may be accomplished by etching the GaN-based nitride semiconductor layer until the n-type GaN layer constituting the n-type layer is exposed. In this case, the (BCl3, Cl2, Ar)-based gas may be used in a dry etching process.

Further, in an embodiment, to perform two different works in one process unlike a conventional method, in which each work is accomplished in an independent process. The process is extended from the process described in that, following the etching process for the GaN-based semiconductor layer, an insulating layer for surface passivation is deposited on the etched surface before removing the photoresist pattern. In the case an insulating layer is deposited on the etched surface, the insulating layer may be formed with oxide material including SiO₂, Al₂O₃, HfO₂, TiO₂, and ZrO₂ (but not limited to).

Further, in the case an insulating layer is deposited on the etched surface, the etched surface may be cleaned either with diluted NaOH, KOH, or TMAH (but limited to) chemical with an etching rate of <10 nm/minute, followed by a rinse of de-ionized water, or only with de-ionized water for cleaning without treatment of the diluted chemical. After the etched surface is cleaned, the etched surface must be treated with oxygen plasma. The O₂-plasma treatment may last as long as the photoresist pattern is thick enough to do a conventional lift-off process, and the RF power of O₂-plasma may be 1˜2,000 W.

Further, the present disclosure describes that in the case the ZnO-based oxide semiconductor layer is deposited on the mesa-patterned epi wafer composed of GaN-based nitride semiconductor layers, the step for etching GaN-based nitride semiconductor layers may be skipped.

Further, the etching process of fabricating the mesa may be finished by cleaning all impurities and residues including photoresist, after the etching process of the present invention, is completely performed.

Further, in addition to the etching process, a thermal annealing process in a gas containing oxygen is another key part of the invented chip process. Oxygen plasma treatment may be necessary before the thermal annealing in an oxygen-containing gas. Further, the purpose of performing the thermal annealing process in a gas containing oxygen is both to remove all kinds of residues and to cure the damaged area possibly caused by the etching process. In addition to these purposes for the thermal annealing process, the thermal annealing process of the present invention may result in a critical effect of increasing the hole concentration in the GaN-based p-type nitride semiconductor layer and the ZnO-based p-type oxide semiconductor layer by the following mechanisms: making the Zn-atoms of ZnO-based oxide semiconductor diffused into the GaN-based p-type nitride semiconductor layer, making Mg-atoms interstitially located in GaN-based nitride semiconductor diffused out to the ZnO-based p-type oxide semiconductor layer, and lowering the O-vacancy density in ZnO-based p-type oxide semiconductor and TCO layers.

Further, in some embodiments, a lateral type ZOGaN LED and a flip-chip type ZOGaN LED with an Ag-based reflective electrode may be manufactured by using the etching process of the present invention described above. These ZOGaN LEDs may be composed of a 70 nm-thick ITO layer as a TCO transparent electrode protection layer.

Further, the p-type layer of the ZOGaN LED/LD is composed of a ZnO-based p-type oxide semiconductor and a GaN-based p-type nitride semiconductor in a specific embodiment. After forming a photoresist pattern of 550×550 μm² in a conventional photolithographic process to fabricate a lateral-type ZOGaN LED, the ITO electrode layer and the ZnO-based oxide semiconductor layer are etched as a specific embodiment of the present invention. The ITO transparent electrode may be fully etched for 4 minutes at an etch rate of 25 nm per minute in a dry etching process with the (BCl₃, Cl₂, Ar)-based mixed gas, but not limited to.

Further, etching the ZnO-based oxide layer with diluted Ferric Chloride solution may be started after the ITO etching process is finished. In this case, the ZnO-based oxide layer may be etched at an etching rate of 500 nm/min by using diluted Ferric Chloride. Then the process of etching the ZnO-based oxide semiconductor layer and the ITO layer may be finished by cleaning the photoresist and residues with solvents and water. After the ITO and ZnO layers are fully etched out, another photoresist pattern is formed to fabricate the p-n junction mesa by etching the GaN-based nitride semiconductor layers. In this case, the photoresist pattern must be slightly larger than the etched ITO/ZnO pattern. Then, the GaN-based nitride semiconductor layers may be etched in a dry etching process with the (BCl₃, Cl₂, Ar)-based mixed gas until the n-type GaN layer constituting the n-type layer structure. Finally, the etching process of the present invention for fabricating the p-n junction mesa of the lateral-type ZOGaN LED may be finished by cleaning the etched surface. The mesa formed after the etching process of the present invention is depicted. All steps of the etching process to form the p-n junction mesa are completed by cleaning the etched wafers with solvents and water. Further, after the etching process is finished, a thermal annealing process is performed at 300° C.˜700° C., preferably 450° C.˜600° C. for 0.1˜600 minutes, preferably 10˜60 minutes in a gas containing oxygen, preferably air.

Further, an additional thermal annealing process in the nitrogen atmosphere may be performed if necessary to improve the electrical conductivity of the ITO electrode layer before depositing the metal p-/n-electrodes. After the cleaning process and before the thermal annealing process, in some cases, a process of treating with oxygen plasma the surface of the p-n junction mesa may be performed to remove impurities and recover the damage caused in the etching process, in which the power of oxygen plasma and the treatment time are 250 W/100 W (ICP/RF)) and 5˜20 minutes, respectively.

Further, for the lateral-type ZOGaN LED, the metal n-electrode on the open surface of the etched n-GaN and the metal p-electrode on the surface of the ITO layer may be formed in a conventional metal lift-off process. Further, by using the etching process of the present invention, ITO, ZnO, and GaN-based nitride semiconductors could be selectively and precisely etched to fabricate the lateral-type ZOGaN LED/LD.

Further, in an embodiment, fabricating a ZOGaN LED, a flip-chip type ZOGaN LED was made with an ITO electrode layer and a reflective metal layer in the size of 1000×1000 μm². After forming a photoresist of the mesa area in conventional photolithography, the ITO electrode may be first etched for 4 minutes at an etch rate of 25 nm per minute in a dry etching process with the (BCl₃, Cl₂, Ar)-based mixed gas, and then the p-type ZnO layer is etched in the wet etching process with diluted Ferric Chloride solution. In this case, the p-type ZnO layer may be completely removed in the area not covered with photoresist in a wet etching process, of which the etching rate and the etching time may be 2 um per minute and about 30 seconds so that an undercut etching of 1 μm can be accomplished. Once the p-type ZnO layer is etched out by the above-described wet etching process, subsequently the GaN-based nitride semiconductor layers are etched to fabricate the mesa in the dry etching process with a conventional (BCl₃, Cl₂, Ar)-based mixed gas until the n-type GaN layer constituting the n-type layer structure is exposed. Finally, the etched surface may be cleaned in a conventional cleaning process with solvents and water. After all processes to form the p-n junction mesa, the thermal annealing in the oxygen atmosphere should be performed to remove the residues and cure the damage at 300° C.˜700° C., preferably 450° C.˜600° C. for 0.1˜600 minutes, preferably 10˜60 minutes in a gas containing oxygen including air.

Further, in some embodiments, after the etching process and before the thermal annealing process, the whole surface of the p-n junction mesa may be treated with oxygen plasma to remove impurities and recover the damage caused in the etching process, in which the RF power of oxygen plasma and the treatment time are 1˜2,000 W and 0.1˜60 minutes, respectively. Finally, the reflective metal layer and the n-/p-electrodes may be formed in a conventional metal lift-off process to finish fabricating the flip-chip type ZOGaN LED.

Further, in an embodiment of the present invention, it is possible with the invented etching process to make the distance (δ) between the edge lines of the etched ZnO and GaN-based nitride semiconductor layers less than 1 μm without using special equipment such as an ultra-precise stepper. Therefore, the etching process of the present invention may be useful to fabricate small ZOGaN LEDs sized in a few micrometers or even sub-micrometers, which are required for the next generation of micro-LED displays.

Further, the present disclosure describes the process for fabrication of the ZOGaN LED/LD, wherein the ZOGaN LED/LD comprises a GaN-based nitride semiconductor layer, a ZnO-based oxide semiconductor layer, and a transparent electrode layer sequentially stacked in structure. The chip process consisted of the steps, wherein the first step is a photolithographic process to form a photoresist pattern required for etching the transparent electrode layer and the ZnO-based oxide semiconductor layer; the second step is a dry etching process with a gas to etch the transparent electrode layer; the third step is an etching process to etch the ZnO-based oxide semiconductor layer; the fourth step is a cleaning process to remove the photoresist and residues; the fifth step is a photolithographic process to form a photoresist pattern required for etching the GaN-based nitride semiconductor layer; the sixth step is a dry etching process with a gas to etch the GaN-based nitride semiconductor layer; the seventh step is a cleaning process to remove the photoresist and residues; the final step is a thermal annealing process to remove the impurities and recover the damaged surface caused in the previous steps.

Further, the present disclosure describes, the process consisting of the steps, wherein the first step is a photolithographic process to form a photoresist pattern required for etching the transparent electrode layer, the ZnO-based oxide semiconductor layer, and the GaN-based nitride semiconductor layer; the second step is a dry etching process with a gas to etch the transparent electrode layer; the third step is an etching process to etch the ZnO-based oxide semiconductor layer; the fourth step is a dry etching process with a gas to etch the GaN-based nitride semiconductor layer; the fifth step is a cleaning process to remove the photoresist and residues; the final step is a thermal annealing process to remove the impurities and recover the damaged surface caused in the previous steps.

Further, the present disclosure describes, a chip process consisting of the steps, wherein the first step is a photolithographic process to form a photoresist pattern required for etching the transparent electrode layer, the ZnO-based oxide semiconductor layer, and the GaN-based nitride semiconductor layer; the second step is a dry etching process with a gas to etch the transparent electrode layer; the third step is an etching process to etch the ZnO-based oxide semiconductor layer; the fourth step is a dry etching process with a gas to etch the GaN-based nitride semiconductor layer; the fifth step is a surface treatment process to clean the etched surface; the sixth step is to deposit an insulating layer for surface passivation; the seventh step is a cleaning process to remove the photoresist and residues; the final step is a thermal annealing process to remove the impurities and recover the damaged surface caused in the previous steps.

Further, in some embodiments, the dry etching process, wherein the transparent electrode layer and GaN-based nitride semiconductor are etched much more efficiently and faster than ZnO-based oxide semiconductor.

Further, in some embodiments, the dry etching process, wherein the gas is the mixture composed of BCl₃, Cl₂, and Ar gases. Further, in an embodiment, the surface treatment process consists of a chemical cleaning process and an oxygen plasma treatment process, wherein the etched surface is treated by oxygen plasma after cleaning in de-ionized water. Further, in an embodiment, the surface treatment process consists of a chemical cleaning process and an oxygen plasma treatment process, wherein the etched surface is treated by at least one chemical (selected from sodium hydroxide, potassium hydroxide, calcium hydroxide, and barium hydroxide, calcium hydroxide, strontium hydroxide, tetramethylammonium hydroxide), de-ionized water, and oxygen plasma sequentially. Further, in an embodiment, an insulating layer for surface passivation is at least one oxide material selected from SiO₂, Al₂O₃, HfO₂, TiO₂, and ZrO₂.

Further, in some embodiments, the etching process to etch ZnO-based oxide semiconductor is a dry etching process with a gas, wherein ZnO-based oxide semiconductor is etched much more efficiently and faster than the transparent electrode layer and GaN-based nitride semiconductor.

Further, in some embodiments, the dry etching process to etch a ZnO-based oxide semiconductor is performed with a gas, wherein the gas is the mixture of the gases selected from SiH₄, NH₃, CH₄, Cl₂, H₂, and Ar gases.

Further, in some embodiments, the etching process to etch ZnO-based oxide semiconductor is a wet etching process with a chemical, wherein a chemical in liquid or gas phase etches ZnO-based oxide semiconductor much more efficiently and faster than the transparent electrode layer and the GaN-based nitride semiconductor layer.

Further, in some embodiments, the wet etching process to etch a ZnO-based semiconductor is performed with a chemical, wherein the chemical is at least one acid chemical selected from ferric chloride, hydrochloric acid, phosphoric acid, sulfuric acid, nitric acid, perchloric acid, citric acid, ammonium hydroxide.

Further, in some embodiments, the wet etching process to etch a ZnO-based semiconductor is performed with a chemical, wherein the chemical is at least one base chemical selected from sodium hydroxide, potassium hydroxide, calcium hydroxide, barium hydroxide, cesium hydroxide, strontium hydroxide.

Further, in some embodiments, the surface treatment process consists of a chemical cleaning process and an oxygen plasma treatment process, wherein the etched surface is treated by oxygen plasma after cleaning in de-ionized water.

Further, in some embodiments, the thermal annealing process is performed in a gas atmosphere containing oxygen, wherein the annealing temperature and duration are in the range of 300˜700° C. and 0.1˜600 minutes, respectively.

Further, in some embodiments, the thermal annealing process is performed in a gas atmosphere containing oxygen after oxygen plasma treatment, wherein the annealing temperature and duration are in the range of 300˜700° C. and 1˜600 minutes, respectively.

Further, in some embodiments, the oxygen plasma treatment is performed for 0.1˜60 minutes with oxygen plasma, wherein the oxygen plasma is activated with the RF power 1˜2,000 W.

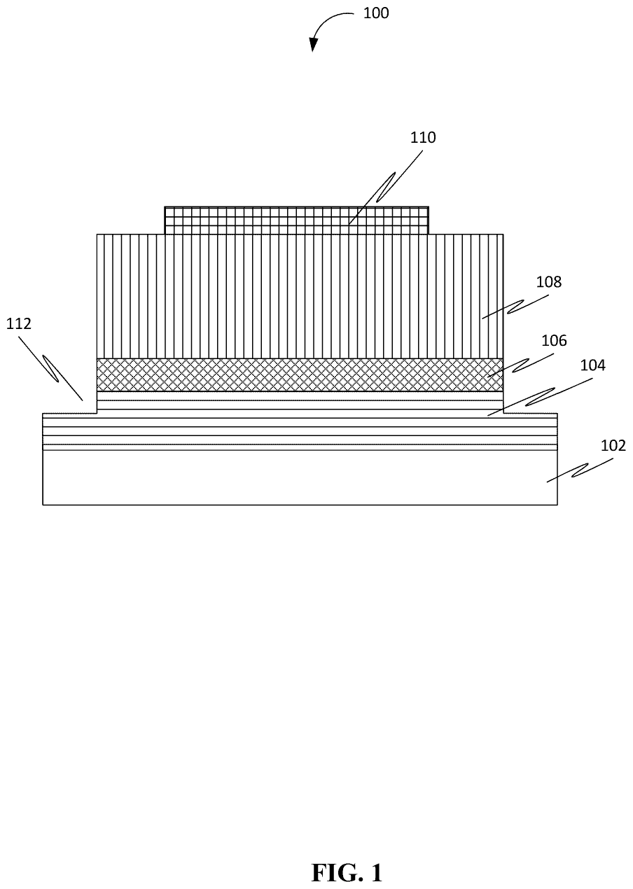

FIG. 1 is a partial sectional view of a device 100 for facilitating emitting light, in accordance with some embodiments. Accordingly, the device 100 may include at least one substrate 102. Further, the at least one substrate 102 may include a semiconductor layer configured to act as an initial layer. Further, the semiconductor layer may include a gallium-nitride based semiconductor layer.

Further, the device 100 may include at least one first layer 104 configured to be placed on the at least one substrate 102. Further, the at least one first layer 104 may be an n-type nitride based semiconductor layer. Further, the at least one first layer 104 may be a base of a mesa structure 112. Further, the base of the mesa structure 112 may be etched using an etching process. Further, the n-type nitride based semiconductor layer may include a gallium-nitride based semiconductor comprising n-type impurities. Further, the etching process may include a dry etching process. Further, the dry etching process may include selective removal of materials using ions, for example, reactive ion etching (RIE), inductively coupled plasma (ICP), etc. Further, the mesa structure 112 may include an area on semiconductor wafer where the semiconductor has not been etched away.

Further, the device 100 may include at least one second layer 106 configured to be placed on the at least one first layer 104. Further, the at least one second layer 106 may be a nitride based semiconductor. Further, the at least one second layer 106 may be a second layer of the mesa structure 112. Further, the second layer of the mesa structure 112 may be etched using the etching process.

Further, the device 100 may include at least one third layer 108 configured to be placed on the at least one second layer 106. Further, the at least one third layer 108 may be a p-type semiconductor layer. Further, the at least one third layer 108 may be a third layer of the mesa structure 112. Further, the third layer of the mesa structure 112 may be etched using a first etching process. Further, the p-type semiconductor layer may include at least one of a gallium-nitride based semiconductor with p-type impurities and a zinc-oxide based semiconductor with p-type impurities. Further, the first etching process may include a wet etching process. Further, the wet etching process may include a selective removal of materials using liquid chemicals. Further, the liquid chemical may include ferric chloride, acidic and basic solutions unreactive to gallium nitride and zinc-oxide, etc.

Further, the device 100 may include at least one fourth layer 110 configured to be placed on the at least one third layer 108. Further, the at least one fourth layer 110 may include at least one transparent electrode. Further, the at least one fourth layer 110 may be a fourth layer of the mesa structure 112. Further, the fourth layer of the mesa structure 112 may be etched using the etching process. Further, the at least one transparent electrode may include a transparent conducting oxide electrode, for example: indium tin oxide, zinc oxide, etc.

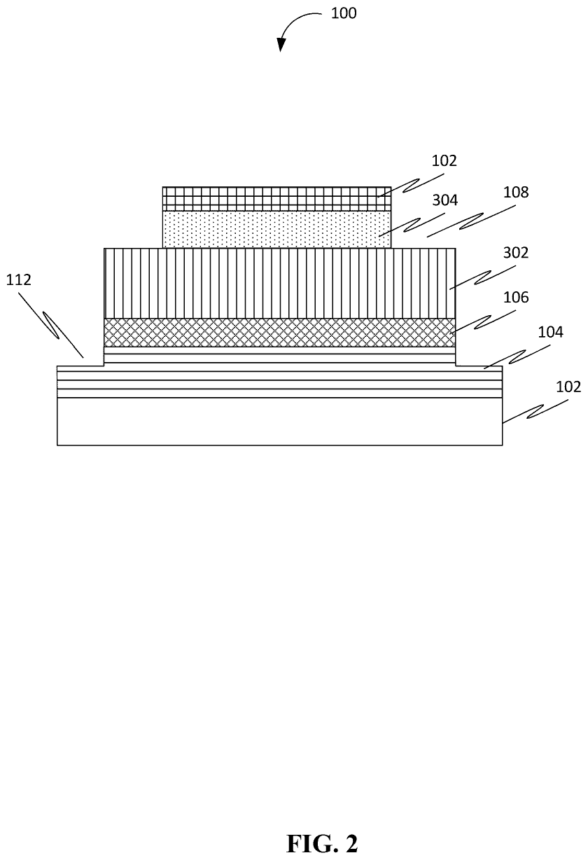

Further, in some embodiments, the at least one third layer 108 may include a first third layer 302, as shown in FIG. 2, comprised of a p-type nitride based semiconductor. Further, the first third layer may be a base of the at least one third layer 108. Further, the at least one third layer 108 may include a second third layer 304, as shown in FIG. 2, comprised of a p-type oxide based semiconductor. Further, the second third layer may be a top of the at least one third layer 108.

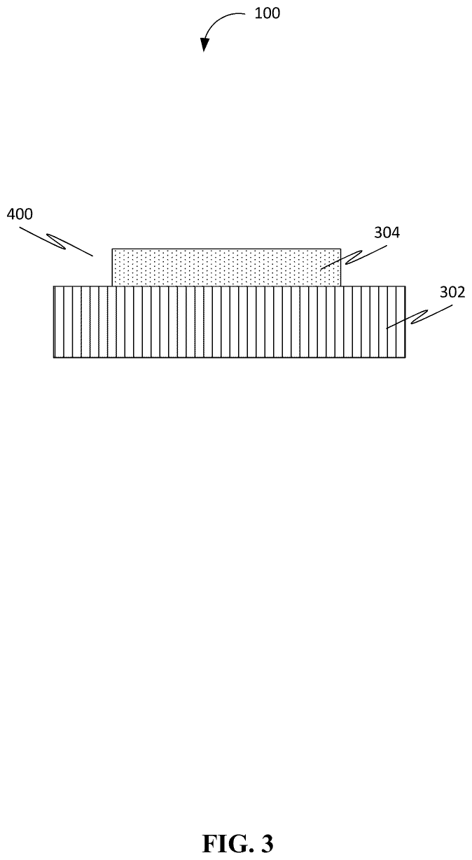

Further, in an embodiment, the first third layer 302 and the second third layer 304 may be creating a p-type layer structure 400, as shown in FIG. 3. Further, the first third layer 302 may be comprised in a bottom part of the p-type layer structure 400. Further, the second third layer 304 may be comprised in an upper part of the p-type layer structure 400.

Further, in an embodiment, the p-type nitride based semiconductor may include a gallium nitride based semiconductor associated with a first lattice distance.

Further, in an embodiment, the p-type oxide based semiconductor may include an oxide semiconductor containing Zn-atom.

Further, in an embodiment, the p-type oxide based semiconductor may include a hexagonal crystal structure associated with a lattice distance larger than the first lattice distance associated with the p-type nitride based semiconductor.

Further, in some embodiments, the at least one third layer 108 may include a p-type oxide based semiconductor.

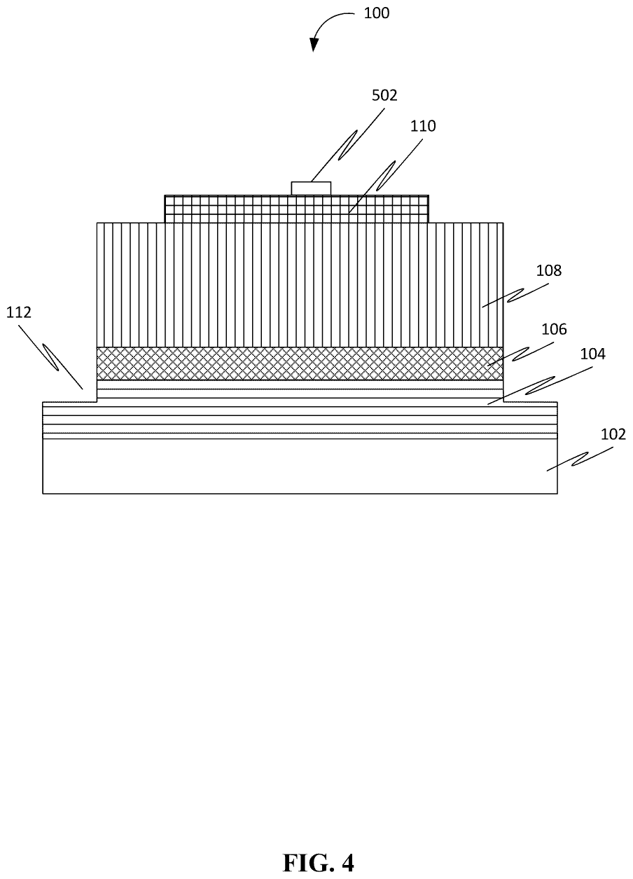

Further, in some embodiments, the device 100 may include at least one metal electrode 502, as shown in FIG. 4. Further, the at least one metal electrode may include an indium-oxide based electrode, a zinc-oxide based electrode, etc.

Further, in some embodiments, the at least one transparent electrode may include at least one transparent conductive oxide layer, for example: indium tin oxide, etc.

Further, in an embodiment, the at least one transparent conductive oxide layer may be associated with a thickness of 70 nm.

Further, in some embodiments, the at least one second layer 106 may include a quantum well. Further, the quantum well may be made of a gallium nitride based semiconductor associated with an energy bandgap.

Further, in some embodiments, the at least one second layer 106 may include a quantum barrier. Further, the quantum barrier may be made of gallium-nitride based semiconductor associated with a first energy bandgap.

Further, in some embodiments, the at least one second layer 106 generates a light based on a recombination of electrons and holes.

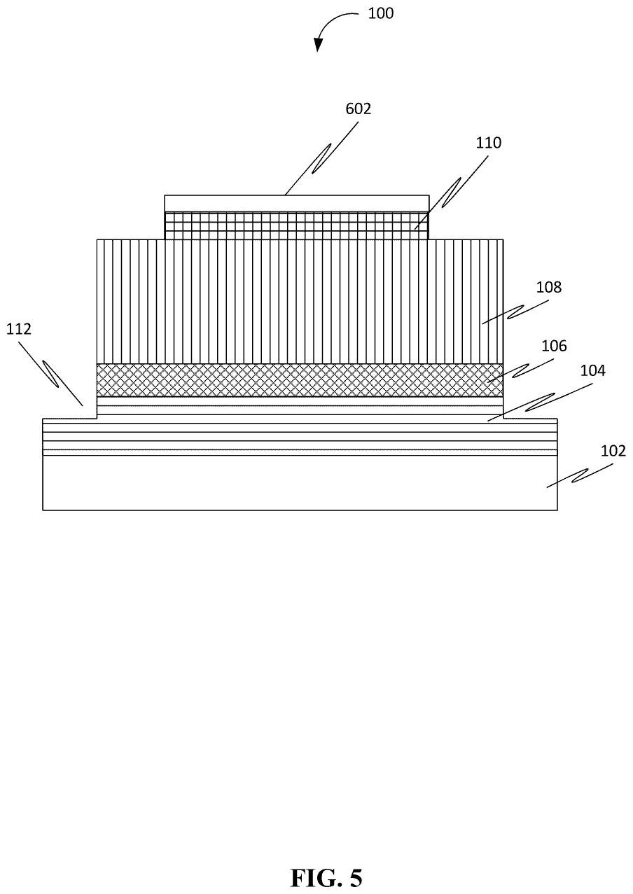

Further, in some embodiments, the device 100 further may include a reflective metal layer 602, as shown in FIG. 5, associated with a size of 1000×1000 μm2. Further, the reflective metal layer 602 may include a reflective metal, for example: indium, gallium, etc.

FIG. 2 is a partial sectional view of the device 100 for facilitating emitting light, in accordance with some embodiments.

FIG. 3 is a partial sectional view of the device 100 for facilitating emitting light, in accordance with some embodiments.

FIG. 4 is a partial sectional view of the device 100 for facilitating emitting light, in accordance with some embodiments.

FIG. 5 is a partial sectional view of the device 100 for facilitating emitting light, in accordance with some embodiments.

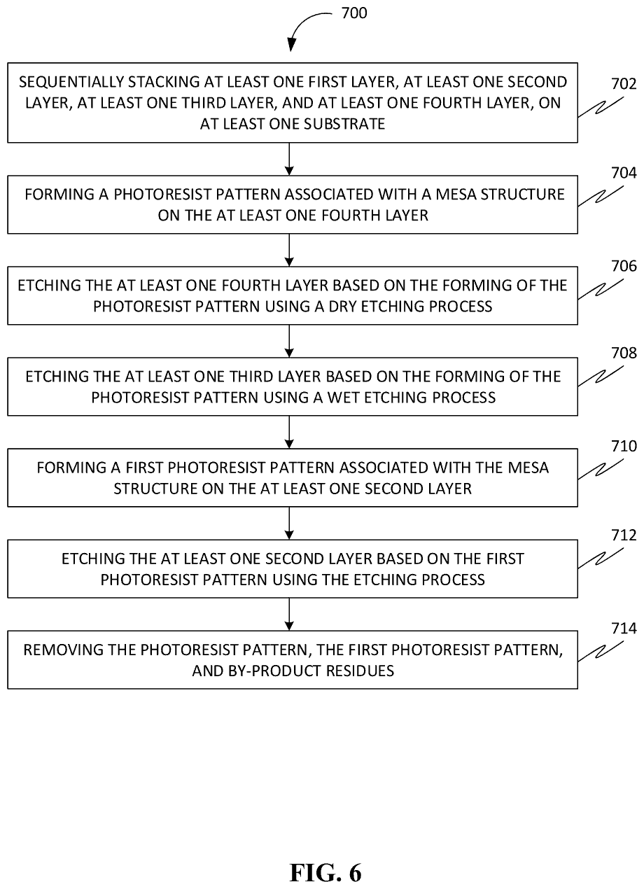

FIG. 6 is a flow diagram of a method 700 for facilitating manufacturing a light emitting device, in accordance with some embodiments. Accordingly, at 702 the method 700 may include sequentially stacking at least one first layer, at least one second layer, at least one third layer, and at least one fourth layer, on at least one substrate. Further, the at least one first layer may be an n-type nitride based semiconductor layer. Further, the at least one second layer may be a nitride based semiconductor layer. Further, the at least one third layer may be a p-type semiconductor layer. Further, the at least one fourth layer may include at least one transparent electrode. Further, the at least one substrate may include a semiconductor layer configured to act as an initial layer. Further, the semiconductor layer may include a gallium-nitride based semiconductor layer. Further, the n-type nitride based semiconductor layer may include a gallium-nitride based semiconductor comprising n-type impurities. Further, the etching process may include a dry etching process. Further, the dry etching process may include selective removal of materials using ions, for example, reactive ion etching (RIE), inductively coupled plasma (ICP), etc. Further, the mesa structure may include an area on semiconductor wafer where the semiconductor has not been etched away. Further, the p-type semiconductor layer may include at least one of a gallium-nitride based semiconductor with p-type impurities and a zinc-oxide based semiconductor with p-type impurities. Further, the first etching process may include a wet etching process. Further, the wet etching process may include a selective removal of materials using liquid chemicals. Further, the liquid chemical may include ferric chloride, acidic and basic solutions unreactive to gallium nitride and zinc-oxide, etc. Further, the at least one transparent electrode may include a transparent conducting oxide electrode, for example: indium tin oxide, zinc oxide, etc.

Further, at 704, the method 700 may include forming a photoresist pattern associated with a mesa structure on the at least one fourth layer. Further, the photoresist pattern may be associated with a size.

Further, at 706, the method 700 may include etching the at least one fourth layer based on the forming of the photoresist pattern using a dry etching process. Further, the dry etching process may include using ionized gases for etching.

Further, at 708, the method 700 may include etching the at least one third layer based on the forming of the photoresist pattern using a wet etching process. Further, the wet etching process may include using chemical solutions, chemical vapors, etc.

Further, at 710, the method 700 may include forming a first photoresist pattern associated with the mesa structure on the at least one second layer. Further, the first photoresist pattern may be associated with a first size.

Further, at 712, the method 700 may include etching the at least one second layer based on the first photoresist pattern using the etching process.

Further, at 714, the method 700 may include removing the photoresist pattern, the first photoresist pattern, and by-product residues.

Further, in some embodiments, the method 700 further may include thermal annealing the mesa structure. Further, the thermal annealing is configured for cleaning impurities and curing damage. Further, the thermal annealing comprises heating of metal above their recrystallization temperature.

Further, in some embodiments, the method 700 further may include using surface passivation with an insulating material on the mesa structure.

Further, in some embodiments, the at least one third layer may include a first third layer comprised of a p-type nitride based semiconductor. Further, the first third layer may be a base of the at least one third layer. Further, the at least one third layer may include a second third layer comprised of a p-type oxide based semiconductor. Further, the second third layer may be a top of the at least one third layer.

Further, in some embodiments, the method 700 further may include treating the mesa structure with oxygen plasma process. Further, the oxygen plasma process comprises cleaning of materials using in an oxygen chamber.

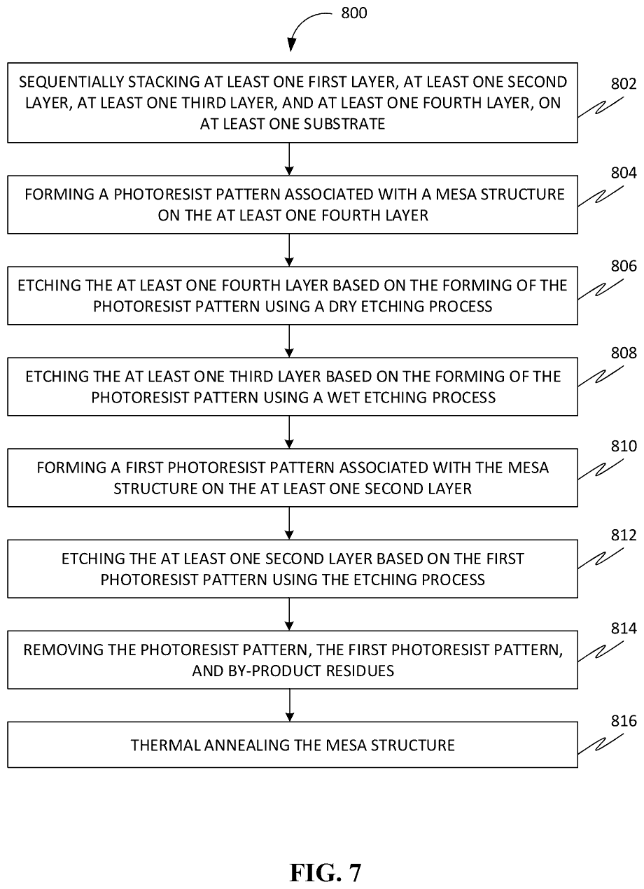

FIG. 7 is a flowchart of a method 800 for facilitating manufacturing a light emitting device, in accordance with some embodiments. Accordingly, at 802, the method 800 may include sequentially placing at least one first layer, at least one second layer, at least one third layer, and at least one fourth layer, on at least one substrate. Further, the at least one first layer may be an n-type nitride based semiconductor layer. Further, the at least one second layer may be a nitride based semiconductor layer. Further, the at least one third layer may be a p-type semiconductor layer. Further, the at least one fourth layer may include at least one transparent electrode.

Further, at 804, the method 800 may include forming a photoresist pattern associated with a mesa structure on the at least one fourth layer. Further, the photoresist pattern may be associated with a size.

Further, at 806, the method 800 may include etching the at least one fourth layer based on the photoresist pattern using a dry etching process. Further, the dry etching process may include using ionized gases for etching.

Further, at 808, the method 800 may include etching the at least one third layer based on the photoresist pattern using a wet etching process. Further, the wet etching process may include using at least one of chemical solutions, chemical vapors, etc.

Further, at 810, the method 800 may include forming a first photoresist pattern associated with the mesa structure on the at least one second layer. Further, the first photoresist pattern may be associated with a first size.

Further, at 812, the method 800 may include etching the at least one second layer based on the first photoresist pattern using the etching process.

Further, at 814, the method 800 may include removing the photoresist pattern, the first photoresist pattern, and by-product residues.

Further, at 816, the method 800 may include thermal annealing the mesa structure. Further, the thermal annealing is configured for cleaning impurities and curing damage.

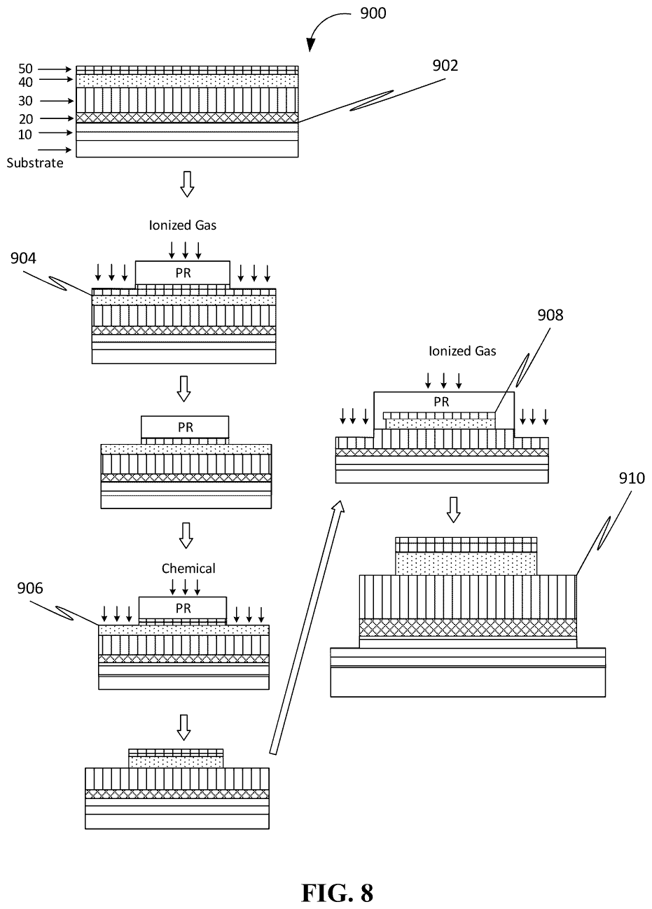

FIG. 8 is a flow diagram of a method 900 for facilitating manufacturing a light emitting device, in accordance with some embodiments. Accordingly, at 902, the method 900 may include sequentially placing at least one first layer, at least one second layer, at least one third layer, at least one fourth layer, and at least one fifth layer on at least one substrate. Further, the at least one first layer may be an n-type nitride based semiconductor layer. Further, the at least one second layer may be a nitride based semiconductor layer. Further, the at least one third layer may be a p-type semiconductor layer. Further, the at least one fourth layer may be an oxide based p-type semiconductor layer. Further, the at least one fifth layer may include at least one transparent electrode.

Further, at 904, the method 900 may include applying a photoresist material on the at least one fifth layer based on a mesa pattern. Further, the method 900 may include etching using a dry etching process the at least one fifth layer based on a mesa pattern.

Further, at 906, the method 900 may include etching using a wet etching process the at least one fourth layer. Further, the method 900 may include removing the photoresist material.

Further, at 908, the method 900 may include applying the photoresist material on the at least one third layer based on a first mesa pattern. Further, the method 900 may include etching using the dry etching process the at least one third layer and the at least one second layer.

Further, at 910, the method 900 may include removing by-products and residues.

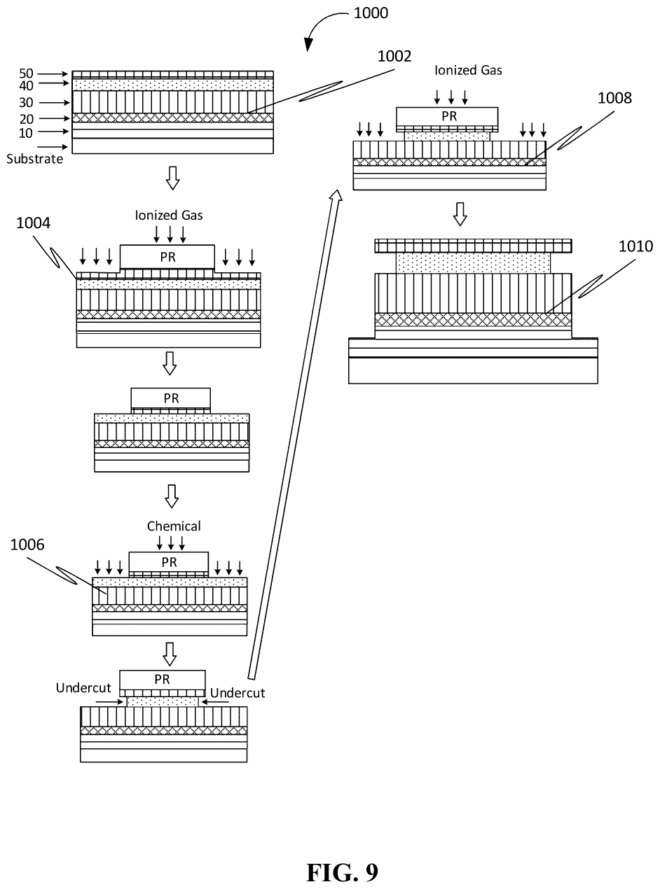

FIG. 9 is a flow diagram of a method 1000 for facilitating manufacturing a light emitting device, in accordance with some embodiments. Accordingly, at 1002, the method 1000 may include sequentially placing at least one first layer, at least one second layer, at least one third layer, at least one fourth layer, and at least one fifth layer on at least one substrate. Further, the at least one first layer may be an n-type nitride based semiconductor layer. Further, the at least one second layer may be a nitride based semiconductor layer. Further, the at least one third layer may be a p-type semiconductor layer. Further, the at least one fourth layer may be an oxide based p-type semiconductor layer. Further, the at least one fifth layer may include at least one transparent electrode.

Further, at 1004, the method 1000 may include applying a photoresist material on the at least one fifth layer based on a mesa pattern. Further, the method 1000 may include etching using a dry etching process the at least one fifth layer based on a mesa pattern.

Further, at 1006, the method 1000 may include etching using a wet etching process the at least one fourth layer.

Further, at 1008, the method 1000 may include etching using the dry etching process the at least one third layer and the at least one second layer.

Further, at 1010, the method 1000 may include removing by-products and residues.

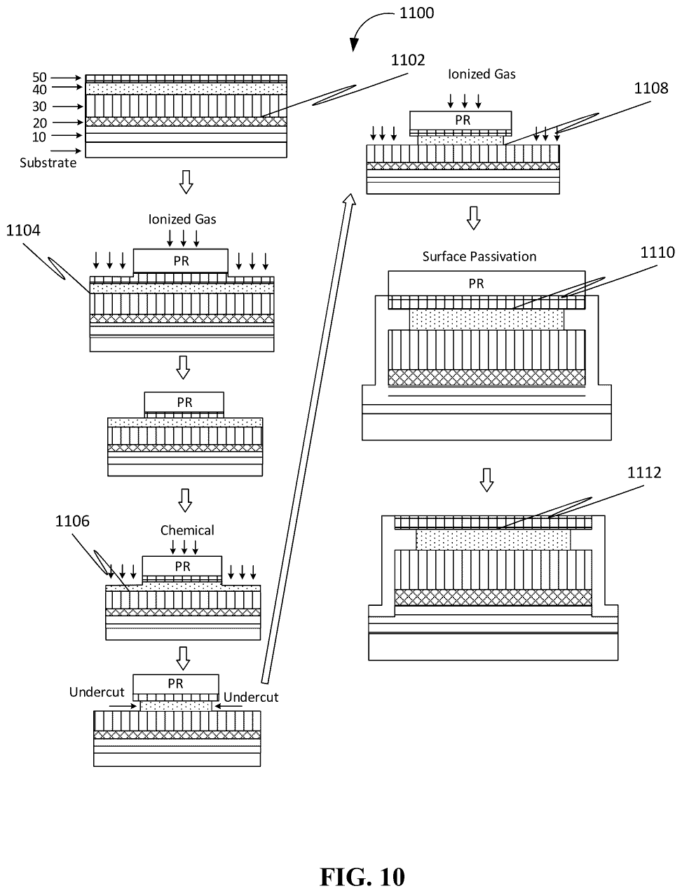

FIG. 10 is a flow diagram of a method 1100 for facilitating manufacturing a light emitting device, in accordance with some embodiments. Accordingly, at 1102, the method 1100 may include sequentially placing at least one first layer, at least one second layer, at least one third layer, at least one fourth layer, and at least one fifth layer on at least one substrate. Further, the at least one first layer may be an n-type nitride based semiconductor layer. Further, the at least one second layer may be a nitride based semiconductor layer. Further, the at least one third layer may be a p-type semiconductor layer. Further, the at least one fourth layer may be an oxide based p-type semiconductor layer. Further, the at least one fifth layer may include at least one transparent electrode.

Further, at 1104, the method 1100 may include applying a photoresist material on the at least one fifth layer based on a mesa pattern. Further, the method 1000 may include etching using a dry etching process the at least one fifth layer based on a mesa pattern.

Further, at 1106, the method 1100 may include etching using a wet etching process the at least one fourth layer.

Further, at 1108, the method 1100 may include etching using the dry etching process the at least one third layer and the at least one second layer.

Further, at 1110, the method 1100 may include surface passivating the mesa.

Further, at 1112, the method 1100 may include removing by-products and residues.

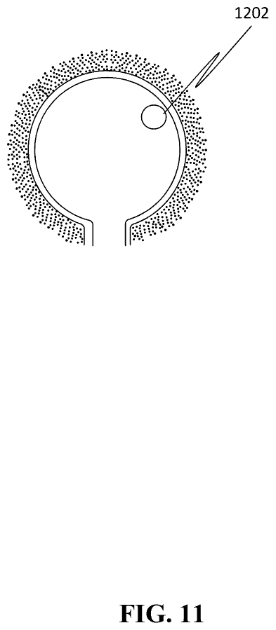

FIG. 11 shows a surface images of a structure of a transparent electrode material (ITO) and ZnO etched with diluted HCl solution, in accordance with some embodiments. As the etching time increases, the residue particles can be removed but lateral etching becomes more serious. Further, 1202 shows the residue particle.

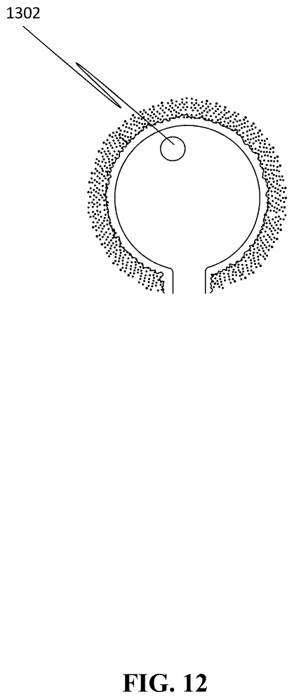

FIG. 12 shows surface images of a structure of a transparent electrode material (ITO) and ZnO etched with diluted HCl solution, in accordance with some embodiments. As the etching time increases, the residue particles can be removed but lateral etching becomes more serious. Further, 1302 shows the residue particle.

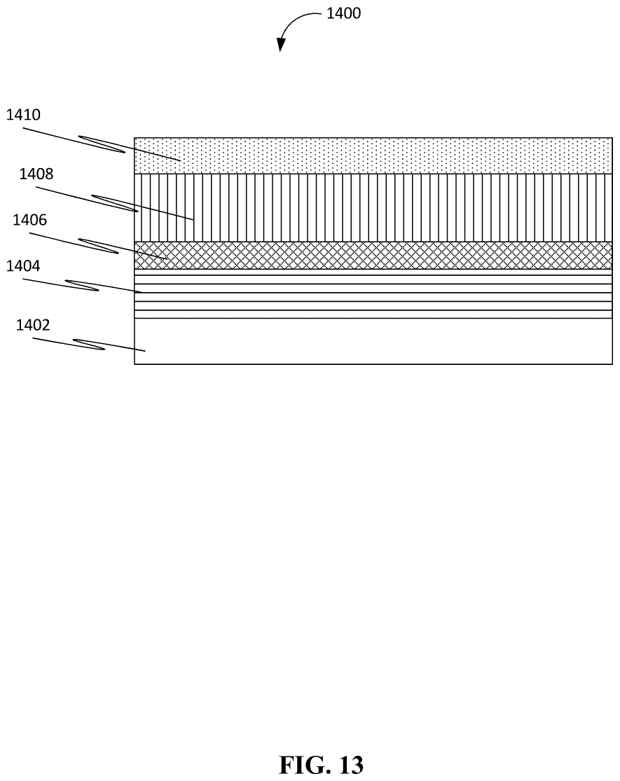

FIG. 13 shows an epi structure 1400 of a ZOGaN light emitting device composed of a ZnO-based oxide semiconductor layer and a GaN-based nitride semiconductor layer, in accordance with some embodiments. Accordingly, the epi structure 1400 comprises a base substrate 1402. Further, the epi structure 1400 comprises a GaN-based n-type nitride semiconductor layer 1402. Further, the epi structure 1400 comprises an active layer 1404 composed of GaN-based nitride semiconductor. Further, the epi structure 1400 comprises a GaN-based p-type nitride semiconductor layer 1406 constituting the bottom part of the p-type layer structure. Further, the epi structure 1400 comprises a ZnO-based oxide semiconductor layer 1408 constituting the upper part of the p-type layer structure. Further, the epi structure 1400 comprises a transparent p-electrode layer 1410.

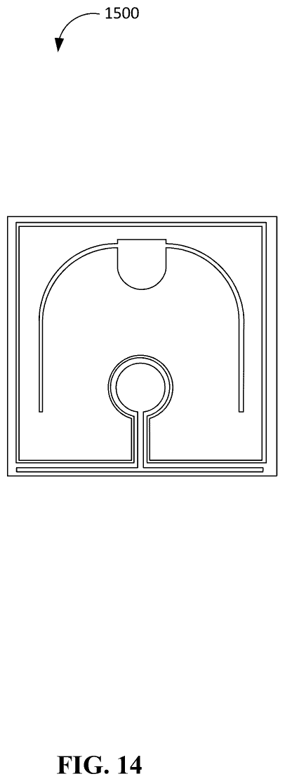

FIG. 14 shows a flip-chip type ZOGaN light emitting device 1500, in accordance with some embodiments.

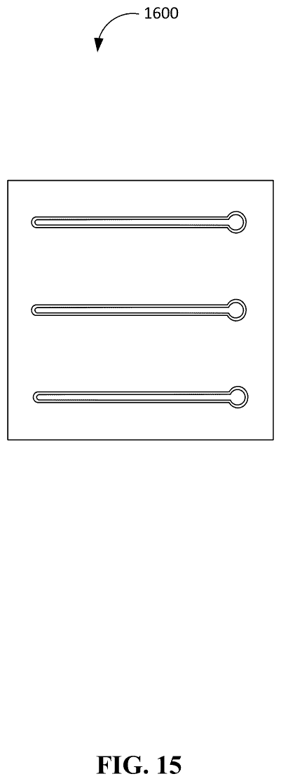

FIG. 15 shows a lateral type ZOGaN light emitting device 1600, in accordance with some embodiments.

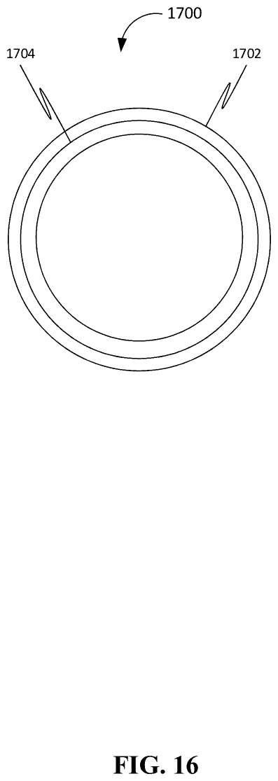

FIG. 16 shows a fine pattern 1700 fabricated using an etching process, in accordance with some embodiments. Accordingly, the pattern comprises an indium tin oxide (ITO)/zinc-oxide (ZnO) etched line 1702 and a gallium-nitride (GaN) etched line 1704.

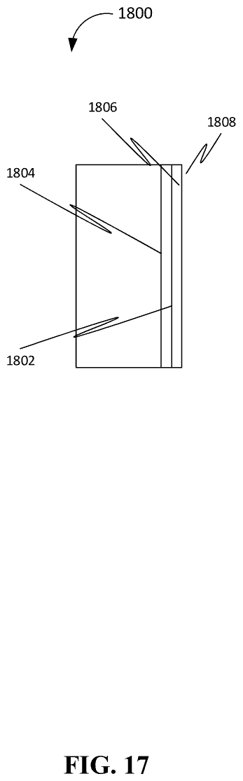

FIG. 17 shows a lateral view of a fine pattern 1800 fabricated using an etching process, in accordance with some embodiments. Accordingly, the pattern comprises an indium tin oxide (ITO)/zinc-oxide (ZnO) etched line 1702 and a gallium-nitride (GaN) etched line 1704. the pattern comprises an indium tin oxide (ITO)/zinc-oxide (ZnO) etched line 1802, a gallium-nitride (GaN) etched line 1804, capping metal line 1806, and a reflective metal line 1808. Further, the GaN etched line 1804 is associated with a thickness of δ˜1 μm.

Although the present disclosure has been explained in relation to its preferred embodiments, it is to be understood that many other possible modifications and variations can be made without departing from the spirit and scope of the disclosure.

### REFERENCES

Etch characterization of GaN using inductively coupled Cl₂/Ar and Cl₂/BCl₃ plasmas, Y. H. Lee, et al., Journal of Vacuum Science Technology A 16(3) (1998), page 1478
Reactive Ion Beam Etching of GaN and AlGaN for Nanostructure Fabrication Using Methane-Based Gas Mixtures, Makoto Endo, et al., Japanese Journal of Applied Physics 41(4B) (2002), page 2689
Dry etching of ZnO films and plasma-induced damage to optical properties, J. S. Park, et al., Journal of Vacuum Science & Technology B 21(2) (2003), page 800
Output power enhancement of GaN light emitting diodes with p-type ZnO hole injection layer, B. J. Kim, et al., Applied Physics Letters 94 (2009), page 103506
Effect of a p-ZnO insertion layer on the external quantum efficiency of GaInN light-emitting diodes, Guan-Bo Lin, et al., Applied Physics Express 8 (2015), page 092102).
Codoping Characteristics of Zn with Mg in GaN, K. S. Kim, et al., Applied Physics Letters 77, page 1123 (2000)
Design of Shallow Acceptors in GaN through Zinc-Magnesium Codoping First-Principles Calculation, Z. Liu, et al., Applied Physics Express 6, page 042104 (2013).
First-Principles Study of intrinsic Point Defects in ZnO: Role of Band Structure, Volume Relaxation, and Finite-Size Effects, P Erhart, et al., Physical Review B73, page 205203 (2006)
Formation of high concentrations of isolated Zn vacancies and evidence for their acceptor levels in ZnO, N. S. Parmar, et al., Journal of Alloys and Compounds 729, page 1031 (2017)

What is claimed is:

1. A device for facilitating emitting light, the device comprising:
at least one substrate;
at least one first layer configured to be placed on the at least one substrate, wherein the at least one first layer is an n-type nitride based semiconductor layer, wherein the at least one first layer is a base of a mesa structure, wherein the base of the mesa structure is etched using an etching process;
at least one second layer configured to be placed on the at least one first layer, wherein the at least one second layer is a nitride based semiconductor, wherein the at least one second layer is a second layer of the mesa structure, wherein the second layer of the mesa structure is etched using the etching process;
at least one third layer configured to be placed on the at least one second layer, wherein the at least one third layer is a p-type semiconductor layer, wherein the at least one third layer is a third layer of the mesa structure, wherein the third layer of the mesa structure is etched using a first etching process; and
at least one fourth layer configured to be placed on the at least one third layer, wherein the at least one fourth layer comprises at least one transparent electrode, wherein the at least one fourth layer is a fourth layer of the mesa structure, wherein the fourth layer of the mesa structure is etched using the etching process.

2. The device of claim 1, wherein the at least one third layer comprising:
a first third layer comprised of a p-type nitride based semiconductor, wherein the first third layer is a base of the at least one third layer; and
a second third layer comprised of a p-type oxide based semiconductor, wherein the second third layer is a top of the at least one third layer.

3. The device of claim 2, wherein the first third layer and the second third layer are creating a p-type layer structure, wherein the first third layer is comprised in a bottom part of the p-type layer structure, wherein the second third layer is comprised in an upper part of the p-type layer structure.

4. The device of claim 2, wherein the p-type nitride based semiconductor comprises a gallium nitride based semiconductor associated with a first lattice distance.

5. The device of claim 2, wherein the p-type oxide based semiconductor comprises an oxide semiconductor containing Zn-atom.

6. The device of claim 5, wherein the p-type oxide based semiconductor comprises a hexagonal crystal structure associated with a lattice distance larger than the first lattice distance associated with the p-type nitride based semiconductor.

7. The device of claim 1, wherein the at least one third layer comprises a p-type oxide based semiconductor.

8. The device of claim 1, further comprising at least one metal electrode.

9. The device of claim 1, wherein the at least one transparent electrode comprises at least one transparent conductive oxide layer.

10. The device of claim 9, wherein the at least one transparent conductive oxide layer is associated with a thickness of 70 nm.

11. The device of claim 1, wherein the at least one second layer comprises a quantum well, wherein the quantum well is made of a gallium nitride based semiconductor associated with an energy bandgap.

12. The device of claim 1, wherein the at least one second layer comprises a quantum barrier, wherein the quantum barrier is made of gallium nitride based semiconductor associated with a first energy bandgap.

13. The device of claim 1, wherein the at least one second layer generates a light based on a recombination of electrons and holes.

14. The device of claim 1, further comprising a reflective metal layer associated with a size of 1000×1000 μm2.

15. A method for manufacturing a light emitting device, the method comprising:
sequentially stacking at least one first layer, at least one second layer, at least one third layer, and at least one fourth layer, on at least one substrate, wherein the at least one first layer is an n-type nitride based semiconductor layer, wherein the at least one second layer is a nitride based semiconductor layer, wherein the at least one third layer is a p-type semiconductor layer, wherein the at least one fourth layer comprises at least one transparent electrode;
forming a photoresist pattern associated with a mesa structure on the at least one fourth layer, wherein the photoresist pattern is associated with a size;
etching the at least one fourth layer based on the forming of the photoresist pattern using a dry etching process, wherein the dry etching process comprises using ionized gases for etching;
etching the at least one third layer based on the forming of the photoresist pattern using a wet etching process, wherein the wet etching process comprises using chemical solutions, chemical vapors, etc.;
forming a first photoresist pattern associated with the mesa structure on the at least one second layer, wherein the first photoresist pattern is associated with a first size;
etching the at least one second layer based on the first photoresist pattern using the etching process; and
removing the photoresist pattern, the first photoresist pattern, and by-product residues.

16. The method of claim 15, further comprising a thermal annealing the mesa structure, wherein the thermal annealing is configured for cleaning impurities and curing damage.

17. The method of claim 15, further comprising using surface passivation with an insulating material on the mesa structure.

18. The method of claim 15, wherein the at least one third layer comprising:
a first third layer comprised of a p-type nitride based semiconductor, wherein the first third layer is a base of the at least one third layer; and
a second third layer comprised of a p-type oxide based semiconductor, wherein the second third layer is a top of the at least one third layer.

19. The method of claim 15 further comprising treating the mesa structure with oxygen plasma process.

20. A method for manufacturing a light emitting device, the method comprising:
sequentially placing at least one first layer, at least one second layer, at least one third layer, and at least one fourth layer, on at least one substrate, wherein the at least one first layer is an n-type nitride based semiconductor layer, wherein the at least one second layer is a nitride based semiconductor layer, wherein the at least one third layer is a p-type semiconductor layer, wherein the at least one fourth layer is comprises at least one transparent electrode;
forming a photoresist pattern associated with a mesa structure on the at least one fourth layer, wherein the photoresist pattern is associated with a size;
etching the at least one fourth layer based on the forming of the photoresist pattern using a dry etching process, wherein the dry etching process comprises using ionized gases for etching;
etching the at least one third layer based on the forming of the photoresist pattern using a wet etching process, wherein the wet etching process comprises using chemical solutions, chemical vapors, etc.;
forming a first photoresist pattern associated with the mesa structure on the at least one second layer, wherein the first photoresist pattern is associated with a first size;
etching the at least one second layer based on the first photoresist pattern using the etching process; and
removing the photoresist pattern, the first photoresist pattern, and by-product residues; and
thermal annealing the mesa structure, wherein the thermal annealing is configured for cleaning impurities and curing damage.
